(19) United States
(12) Patent Application Publication
(10) Pub. No.: US 2025/0151342 A1
(43) Pub. Date: May 8, 2025

(54) FULL AND HALF SINGLE DIFFUSION BREAK WITH STACKED FET

(71) Applicant: INTERNATIONAL BUSINESS MACHINES CORPORATION, ARMONK, NY (US)

(72) Inventors: Chen Zhang, Santa Clara, CA (US); Ruilong Xie, Niskayuna, NY (US); Shay Reboh, Guilderland, NY (US); Junli Wang, Slingerlands, NY (US)

(21) Appl. No.: 18/502,125

(22) Filed: Nov. 6, 2023

(51) Int. Cl. H01L 29/06; H01L 21/8238; H01L 27/092; H01L 29/423; H01L 29/66; H01L 29/775; H01L 29/786

(52) U.S. Cl. CPC H10D 62/116; H10D 30/014; H10D 30/43; H10D 30/6735; H10D 30/6757; H10D 62/121; H10D 64/017; H10D 84/017; H10D 84/0188; H10D 84/038; H10D 84/85

(57) ABSTRACT

Embodiments of present invention provide a semiconductor structure. The structure includes a first group of field-effect-transistors (FETs); a second group of FETs on top of the first group of FETs; a first half-single-diffusion-break (H-SDB) underneath and being separated from one of the FETs of the second group by a middle-dielectric-insulator (MDI) layer; and a second H-SDB on top of and being separated from one of the FETs of the first group by the MDI layer, where the first H-SDB insulates a source/drain (S/D) region of a first FET of the first group of FETs from a S/D region of a second FET of the first group of FETs, and the second H-SDB insulates a S/D region of a first FET of the second group of FETs from a S/D region of a second FET of the second group of FETs. A method of forming the same is also provided.

### BACKGROUND

The present application relates to manufacturing of semiconductor integrated circuits. More particularly, it relates to forming single-diffusion-breaks of different types in connection with forming stacked field-effect-transistors and structures formed thereby.

As semiconductor industry moves towards smaller node, field-effect-transistors (FETs) such as, for example, nanosheet transistors or nanosheet FETs are formed in a way of being stacked together in an effort to aggressively fit in more transistors in a given real estate of a chip. On the other hand, two horizontally neighboring transistors, particularly transistors of different types, often need to be insulated from each other. This is usually achieved by replacing a stack of two gates, one at a top and one at a bottom of the stack, with a dielectric material to form a single-diffusion-break. However, replacing the stack of two gates in exchange for a single-diffusion-break may waste precious real estate spaces as there are situations where only the transistors at the top or at the bottom of the stack, but not both, needs to be insulated.

### SUMMARY

Embodiments of present invention provide a semiconductor structure. The semiconductor structure includes a first group of field-effect-transistors (FETs); a second group of FETs on top of the first group of FETs; and a half-single-diffusion-break (H-SDB) directly underneath one of the FETs of the second group and being separated from the one of the FETs of the second group by a middle-dielectric-insulator (MDI) layer, where the H-SDB insulates a source/drain (S/D) region of a first FET of the first group of FETs from a S/D region of a second FET of the first group of FETs. The use of the H-SDB saves a real estate space above the H-SDB that is used in forming another FET.

In one embodiment, the H-SDB is a first H-SDB and the semiconductor structure further includes a second H-SDB directly on top of one of the FETs of the first group and being separated from the one of the FETs of the first group by the MDI layer, where the second H-SDB insulates a S/D region of a first FET of the second group of FETs from a S/D region of a second FET of the second group of FETs. The use of the second H-SDB saves a real estate space below the second H-SDB, or more specifically below the MDI layer, for forming an additional FET.

In another embodiment, the semiconductor structure further includes a full-single-diffusion-break (F-SDB) with a first portion underneath the MDI layer and a second portion above the MDI layer, where the first portion of the F-SDB insulates a S/D region of a third FET of the first group of FETs from a S/D region of a fourth FET of the first group of FETs, and the second portion of the F-SDB insulates a S/D region of a third FET of the second group of FETs from a fourth FET of the second group of FETs.

In one aspect, the first and the second FET of the first group of FETs have opposite polarities, and in another aspect the first and the second FET of the second group of FETs have opposite polarities.

In one embodiment, the one of the FETs of the second group is a nanosheet transistor and the H-SDB is directly underneath a metal gate of the nanosheet transistor, the metal gate of the nanosheet transistor surrounding a set of nanosheets.

In another embodiment, the one of the FETs of the first group is a nanosheet transistor and the second H-SDB is directly on top of a metal gate of the nanosheet transistor, the metal gate of the nanosheet transistor surrounding a set of nanosheets.

Embodiments of present invention further provide a method of forming a semiconductor structure. The method includes forming a first group of metal gates on top of a substrate; forming a second group of metal gates on top of a middle-dielectric-insulator (MDI) layer, the MDI layer being on top of the first group of metal gates; forming a full-single-diffusion-break (F-SDB) through the first and the second group of metal gates; forming a first half-single-diffusion-break (H-SDB) through the first group of metal gates; and forming a second H-SDB through the second group of metal gates.

In one embodiment, forming the F-SDB and forming the second H-SDB includes creating a first opening by removing one of the metal gates of the second group and one of the metal gates of the first group, the one of the metal gates of the first group being directly underneath the one of the metal gates of the second group; creating a second opening by removing another one of the metal gates of the second group to expose a top surface of the MDI layer; filling the first opening with a dielectric material to form the F-SDB, the F-SDB having a first portion underneath the MDI layer and a second portion above the MDI layer; and filling the second opening with the dielectric material to form the second H-SDB.

In another embodiment, forming the first H-SDB includes creating a third opening, from a backside of the substrate, by removing another one of the metal gates of the first group to expose a bottom surface of the MDI layer; and filling the third opening with the dielectric material to form the first H-SDB.

According to one embodiment, the method includes forming the first group of metal gates and the second group of metal gates in a single replacement-metal-gate process.

According to one embodiment, the method includes epitaxially growing a first group of source/drain (S/D) regions from a first and a second end of multiple sets of nanosheets below the MDI layer. According to another embodiment, the method further includes forming an interlevel dielectric layer on top of the first group of S/D regions; and epitaxially growing a second group of S/D regions from a first and a second end of multiple sets of nanosheets above the MDI layer.

### BRIEF DESCRIPTION OF THE DRAWINGS

The present invention will be understood and appreciated more fully from the following detailed description of embodiments of present invention, taken in conjunction with accompanying drawings of which:

FIGS. 1-12 are demonstrative illustrations of cross-sectional view of a semiconductor structure at various steps of manufacturing thereof according to embodiments of present invention; and

FIG. 13 is a demonstrative illustration of a flow-chart of a method of manufacturing a semiconductor structure according to embodiments of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity, or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the ease of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Likewise, the terms “on”, “over”, or “on top of” that are used herein to describe a positional relationship between two layers or structures are intended to be broadly construed and should not be interpreted as precluding the presence of one or more intervening layers or structures.

Moreover, although various reference numerals may be used across different drawings, the same or similar reference numbers are used throughout the drawings to denote the same or similar features, elements, or structures, and thus detailed explanations of the same or similar features, elements, or structures may not be repeated for each of the drawings for economy of description. Labelling for the same or similar elements in some drawings may be omitted as well in order not to overcrowd the drawings.

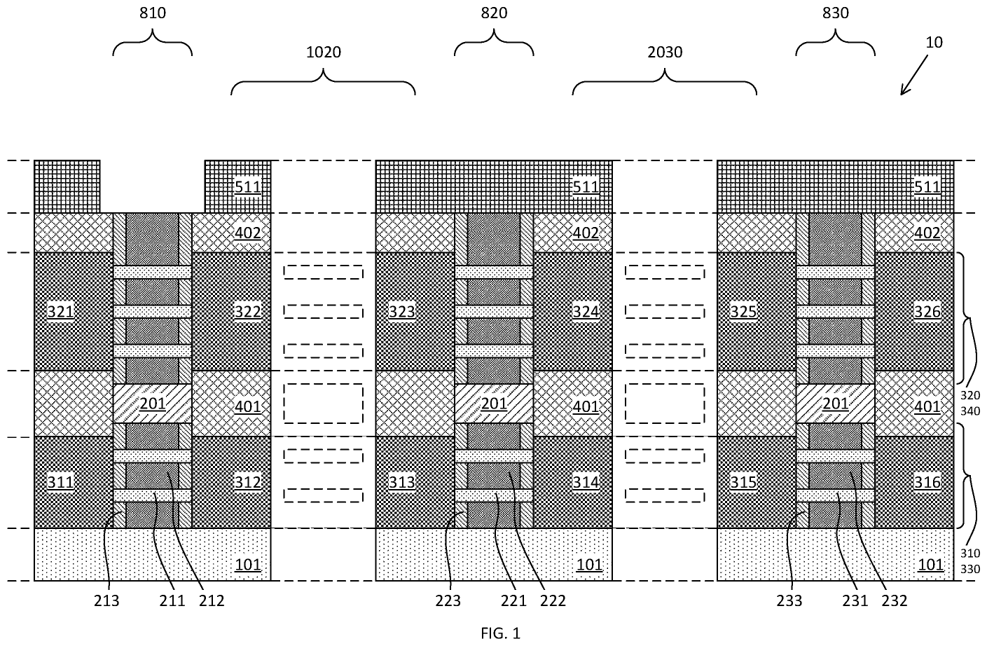

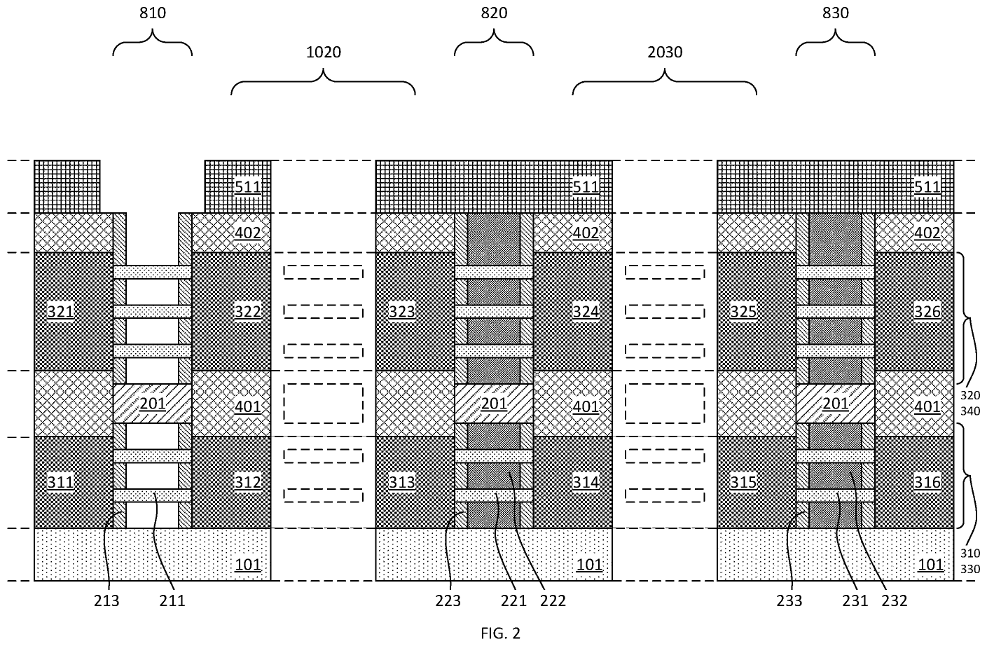

FIG. 1 is a demonstrative illustration of cross-sectional view of a semiconductor structure in a step of manufacturing thereof according to one embodiment of present invention. More particularly, the semiconductor structure includes multiple stacked field-effect-transistors (FETs). The cross-section illustrated in FIG. 1, as well as those illustrated in FIGS. 2-12, is made across gates of the multiple stacked FETs and in a direction along the length of the gates.

Embodiments of present invention provide forming a semiconductor structure 10 that includes multiple stacked FETs, such as stacked nanosheet transistors or stacked nanosheet FETs. However, embodiments of present invention are not limited in this aspect and may be applied to other types of transistors and/or active devices. Some of the multiple stacks of FETs may be insulated or separated from each other by one or more single-diffusion-breaks (SDBs) such as, for example, a full-SDB or a half-SDB. Here, assuming the multiple stacks of FETs include a first group of FETs, as well as a second group of FETs stacked on top of the first group of FETs, a full-SDB (F-SDB) refers to a SDB that is formed to insulate or separate both the first group of FETs and the second group of FETs. On the other hand, a half-SDB (H-SDB) refers to a SDB that is formed to insulate or separate either the first group of FETs or insulate or separate the second group of FETs. Description of F-SDB and H-SDB are provided below in more details. Alternatively, the F-SDB may be referred to as a type-1 SDB (T1-SDB) and the H-SDB may be referred to as a type-2 SDB (T2-SDB).

The multiple stacked FETs may be formed, for example, in a first region 1020 and a second region 2030. One or more SDBs may be formed, for example, in a first area 810, a second area 820, and a third area 830. Hereinafter, description of embodiments of present invention may be focused mainly on forming SDBs in the first, the second, and the third area 810, 820, and 830. Description and/or illustration of the multiple stacks of FETs, except some source/drain regions, may be omitted and/or may be illustrated in FIGS. 1-12 in dashed lines to the extent that their omission does not hinder the description of embodiments of present invention.

More particularly, embodiments of present invention provide receiving or providing a semiconductor substrate 101; forming a first group of metal gates 310 of a first group of FETs 330 on top of the semiconductor substrate 101; forming a second group of metal gates 320 of a second group of FETs 340 on top of and being separated from the first group of metal gates 310 by a middle-dielectric insulator (MDI) layer 201. In other words, the second group of metal gates 320 may be formed on top of the MDI layer 201, and the MDI layer 201 is on top of the first group of metal gates 310.

More specifically, the first group of metal gates 310 and the second group of metal gates 320 may include, in the first area 810, a stack of metal gates including a first metal gate below the MDI layer 201 and a second metal gate above the MDI layer 201. The first metal gate and the second metal gate may each include a set of nanosheets 211 surrounded by a gate metal 212. In one embodiment, the set of nanosheets 211 may be silicon (Si) nanosheets and the gate metal 212 may include a gate dielectric layer, one or more layers of work-function metals such as a titanium-nitride (TiN) layer, and one or more layers of conductive materials such as tungsten (W), ruthenium (Ru), cobalt (Co) or other suitable materials. The first metal gate and the second metal gate may be formed together in a single replacement-metal-gate (RMG) process. Inner spacers 213 may be formed before the RMG process and may be at a first and a second end of the gate metal 212 to insulate the gate metal 212 from surrounding epitaxially formed source/drain (S/D) regions. The inner spacers 213 may be made of dielectric materials such as, for example, silicon-nitride (SiN) or silicon-oxide (SiO₂).

The first group of metal gates 310 and the second group of metal gates 320 may further include a first and a second metal gate, one below and one above the MDI layer 201, in the second area 820 and in the third area 830 respectively. For example, the first and the second metal gate in the second area 820 may each include a set of nanosheets 221 surrounded by a gate metal 222. Inner spacers 223 may be formed at a first and a second end of the gate metal 222 to insulate the gate metal 222 from surrounding S/D regions. The first and the second metal gate in the third area 830 may each include a set of nanosheets 231 surrounded by a gate metal 232. Inner spacers 233 may be formed at a first and a second end of the gate metal 232 to insulate the gate metal 232 from surrounding S/D regions.

The first group of metal gates 310 and the second group of metal gates 320 may include additional stacks of metal gates, for example, in the first region 1020, in the second region 2030, and in other regions not illustrated. The first group of metal gates 310 may be part of the first group of FETs 330 below the MDI layer 201 and the second group of metal gates 320 may be part of the second group of FETs 340 above the MDI layer 201. In one embodiment, both the first and the second group of FETs may be nanosheet transistors or nanosheet FETs.

Embodiments of present invention further provide epitaxially growing a first group of source/drain (S/D) regions, such as SiGe S/D regions, from a first and a second end of the multiple sets of nanosheets underneath the MDI layer 201. For example, a first bottom set of S/D regions 311 and 312 may be formed or epitaxially grown from a first and a second end of the set of nanosheets 211 in the first area 810. A second bottom set of S/D regions 313 and 314 may be formed or epitaxially grown from a first and a second end of the set of nanosheets 221 in the second area 820. A third bottom set of S/D regions 315 and 316 may be formed or epitaxially grown from a first and a second end of the set of nanosheets 231 in the third area 830. The first group of S/D regions may include additional S/D regions formed in other areas such as in the first and the second region 1020 and 2030.

A first interlevel dielectric (ILD) layer 401, such as a layer of SIN, SiO2, SiCO, SiBCN, or SiOCN, may be formed on top of and covering the first, the second, and the third bottom set of S/D regions 311, 312, 313, 314, 315, and 316. The first ILD layer 401 may be formed at a position around the MDI layer 201 and may or may not have a same type of dielectric material as the MDI layer 201.

Embodiments of present invention further provide epitaxially growing a second group of S/D regions, such as SiGe S/D regions, from a first and a second end of the multiple sets of nanosheets above the MDI layer 201. For example, a first top set of S/D regions 321 and 322 may be formed or epitaxially grown from a first and a second end of the set of nanosheets 211 in the first area 810. A second top set of S/D regions 323 and 324 may be formed or epitaxially grown from a first and a second end of the set of nanosheets 221 in the second area 820. A third top set of S/D regions 325 and 326 may be formed or epitaxially grown from a first and a second end of the set of nanosheets 231 in the third area 830. The second group of S/D regions may include additional S/D regions formed in other areas such as in the first and the second region 1020 and 2030.

Another dielectric layer such as, for example, a second ILD layer 402 may be formed on top of and covering the first, the second, and the third top set of S/D regions 321, 322, 323, 324, 325, and 326. Subsequently, a chemical-mechanical-polishing (CMP) process may be applied to planarize a top surface of the second ILD layer 402 and to expose top surfaces of the second metal gates in the first, the second, and the third area 810, 820, and 830 and metal gates in other areas such as in the first and the second region 1020 and 2030. It is to be noted here that the formation of the first group of S/D regions below the MDI layer 201 and the second group of S/D regions above the MDI layer 201 may be performed before forming the stacks of metal gates such as those metal gates in the first, the second, and the third area 810, 820, and 830.

Following the formation of the multiple stacks of metal gates and the epitaxial S/D regions next to the first and second ends of the multiple sets of nanosheets, embodiments of present invention provide forming a mask layer, such as an organic planarization (OPL) layer, on top of the second ILD layer 402 and on top of the stacks of metal gates. The mask layer may then be patterned through a lithographic patterning process to create a hard mask 511. The hard mask 511 may have an opening that exposes one of the stacks of metal gates such as, for example, the stack of metal gates in the first area 810.

FIG. 2 is a demonstrative illustration of cross-sectional view of a semiconductor structure in a step of manufacturing thereof according to one embodiment of present invention. More particularly, following the step illustrated in FIG. 1, embodiments of present invention provide applying a selective etch process, using a suitable etchant, to remove the exposed gate metal 212 in the first area 810 that surrounds the set of nanosheets 211 and the MDI layer 201. The selective removal of the gate metal 212 both above and below the MDI layer 201 may leave the set of nanosheets 211 exposed for further processing.

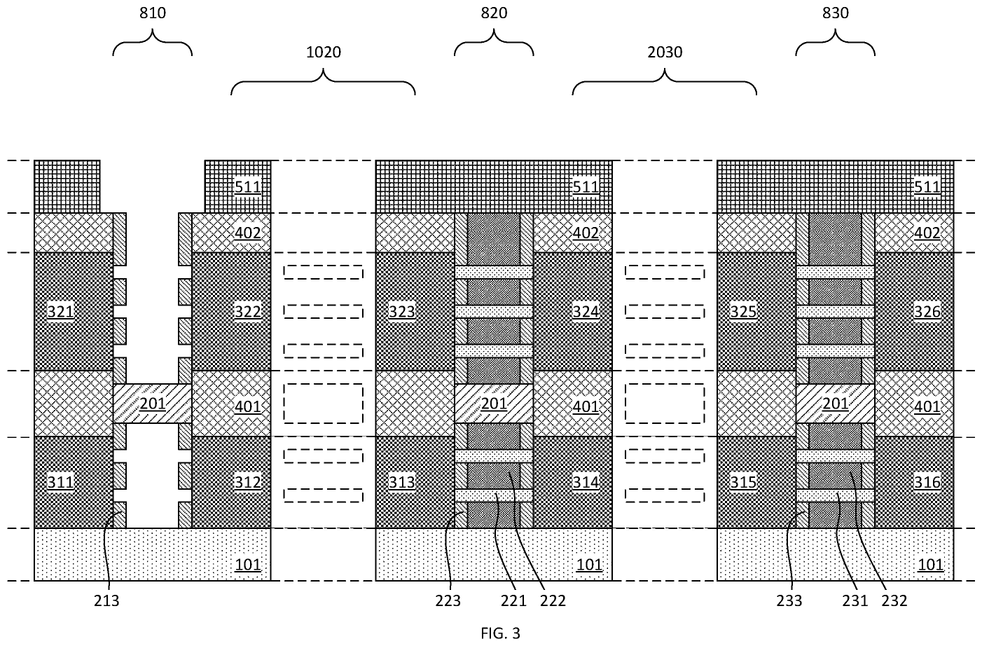

FIG. 3 is a demonstrative illustration of cross-sectional view of a semiconductor structure in a step of manufacturing thereof according to one embodiment of present invention. More particularly, following the step illustrated in FIG. 2, embodiments of present invention provide continuing to remove, in a selective etch process, the set of nanosheets 211 relative to the MDI layer 201 and relative to the inner spacers 213. The further removal of the set of nanosheets 211 therefore creates an opening, for example a first opening, both above and below the MDI layer 201, that is ready for forming a single-diffusion-break (SDB) such as a full-SDB (F-SDB). In other words, a F-SDB may be formed in openings both above and below the MDI layer 201, thereby providing insulation or separation for both the first group of FETs 330 and the second group of FETs 340. Before proceeding to form the F-SDB in the first opening, one embodiment of present invention provides proceeding to create a second opening, either above or below the MDI layer 201 and in this case above the MDI layer 201, for forming a half-SDB (H-SDB) using another metal gate of the second group of metal gates 320 as being described below in more details. In other words, a H-SDB may be formed in an opening either above or below the MDI layer 201, thereby providing insulation or separation for either the first group of FETs 330 or the second group of FETs 340.

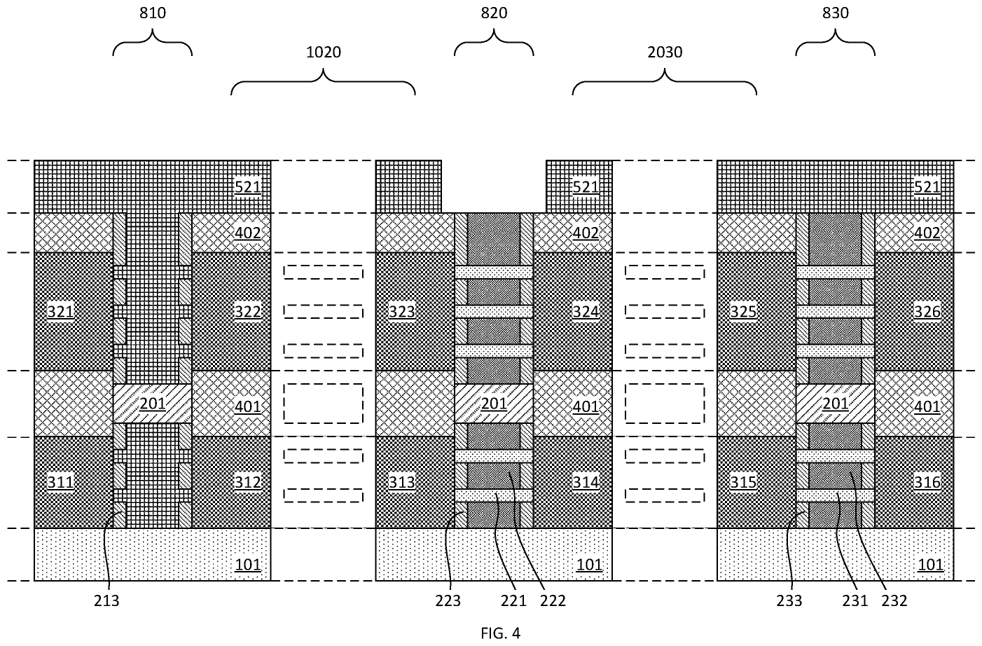

FIG. 4 is a demonstrative illustration of cross-sectional view of a semiconductor structure in a step of manufacturing thereof according to one embodiment of present invention. More particularly, following the step illustrated in FIG. 3, embodiments of present invention provide removing the hard mask 511 from the top of the second ILD layer 402 and the second group of metal gates 320. Another mask layer, such as an OPL layer, may be formed on top of the second ILD layer 402 to cover the multiple stacks of metal gates. Next, the mask layer may be patterned to form a hard mask 521 with an opening that exposes, for example, the stack of metal gates in the second area 820. In the meantime, material of the mask layer may fill the first opening in the first area 810, which provides protection for the first opening in subsequent steps of processing.

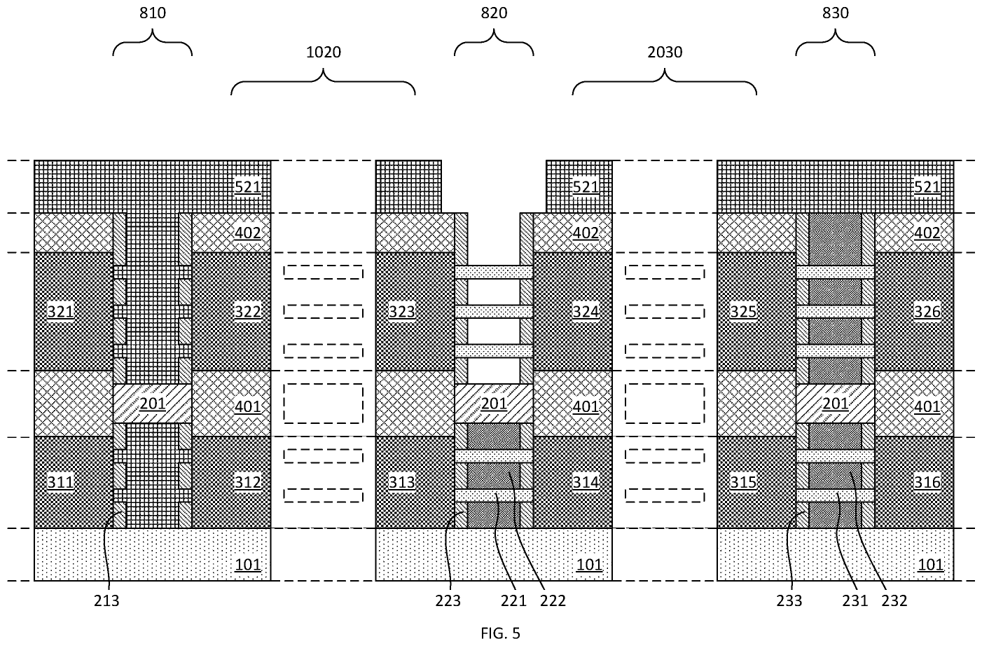

FIG. 5 is a demonstrative illustration of cross-sectional view of a semiconductor structure in a step of manufacturing thereof according to one embodiment of present invention. More particularly, following the step illustrated in FIG. 4, embodiments of present invention provide applying a selective etch process to remove only a portion of the gate metal 222, above the MDI layer 201, which corresponds to gate metal of one of the second group of metal gates 320 in the second area 820. The selective etch process may be timed or controlled such that it stops when a top surface of the MDI layer 201 in the second area 820 is exposed.

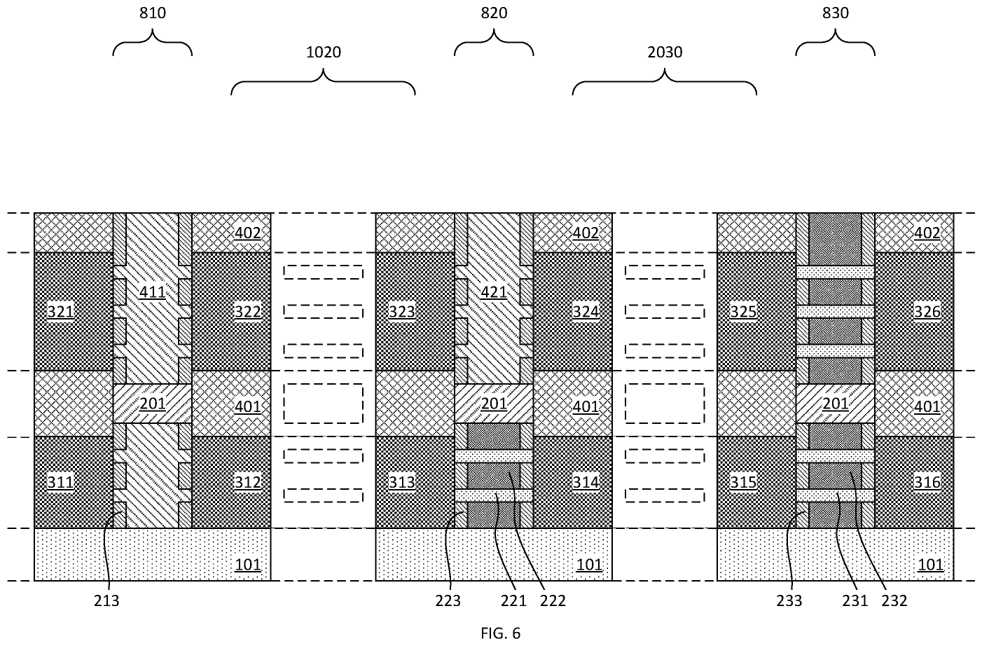

FIG. 6 is a demonstrative illustration of cross-sectional view of a semiconductor structure in a step of manufacturing thereof according to one embodiment of present invention. More particularly, following the step illustrated in FIG. 5, embodiments of present invention provide selectively removing a portion of the set of nanosheets 221 that is above the MDI layer 201 and exposed by the removal of the gate metal 222. The further removal of the portion of the set of nanosheets 221 creates a second opening, in the second area 820, above the MDI layer 201 for forming a H-SDB.

Embodiments of present invention further provide removing the hard mask 521 on top of the second ILD layer 402 and the mask layer material filling the first opening to re-store or re-create the first opening in the first area 810. Next, a dielectric material may be used to fill the first opening to form a F-SDB 411 in the first area 810. The F-SDB 411 may have a top portion, above the MDI layer 201, between a source/drain (S/D) region 321 of a third FET of the second group of FETs 340 and a S/D region 322 of a fourth FET of the second group of FETs 340. The F-SDB 411 may also have a bottom portion, below or underneath the MDI layer 201, between a S/D region 311 of a third FET of the first group of FETs 330 and a S/D region 312 of a fourth FET of the first group of FETs 330. In one embodiment, the third and the fourth FET of the second group of FETs 340 may have opposite polarities and the third and the fourth FET of the first group of FETs 330 may have opposite polarities as well. For example, the third FET of the second group of FETs 340 may be a p-type FET and the fourth FET of the second group of FETs 340 may be an n-type FET, or vice versa. The same may be said for the third and the fourth FETs of the first group of FETs 330. The dielectric material used in forming the F-SDB 411 may be a material same as or different from the dielectric material that forms the MDI layer 201. For example, the dielectric material may be SiN, SiO₂, SiCO, SiBCN, or SiOCN.

A dielectric material, and in one embodiment the same dielectric material as that used in forming the F-SDB 411 above, may be used to fill the second opening to form a H-SDB 421 in the second area 820. The H-SDB 421 may be a second H-SDB (a first H-SDB may be formed later as being described below in more details) and may be formed between a S/D region of a first FET of the second group of FETs 340 and a S/D region of a second FET of the second group of FETs 340. In one embodiment, the first and the second FET of the second group of FETs 340 may have opposite polarities. For example, the first FET of the second group of FETs 340 may be a p-type FET and the second FET of the second group of FETs 340 may be an n-type FET, or vice versa. The H-SDB 421 may be vertically or directly on top of, via the MDI layer 201, a metal gate of the first group of metal gates 310. The metal gate of the first group of metal gates 310 may a metal gate of a nanosheet FET.

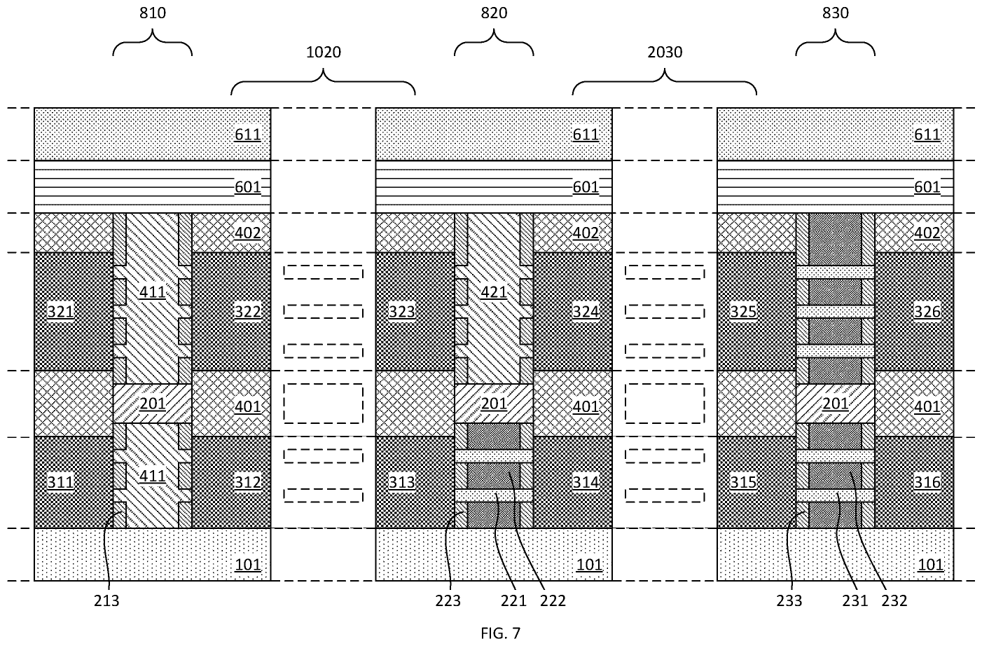

FIG. 7 is a demonstrative illustration of cross-sectional view of a semiconductor structure in a step of manufacturing thereof according to one embodiment of present invention. More particularly, following the step illustrated in FIG. 6, embodiments of present invention provide forming a back-end-of-line (BEOL) structure 601 on top of the F-SDB 411, the H-SDB 421, and the second group of metal gates 320. The BEOL structure 601 may include various interconnects, S/D contacts, and/or gate contacts. Next, a handling wafer 611 may be attached or bonded onto the BEOL structure 601 such that the semiconductor substrate 101 may be flipped upside-down for further processing from a backside of the semiconductor substrate 101.

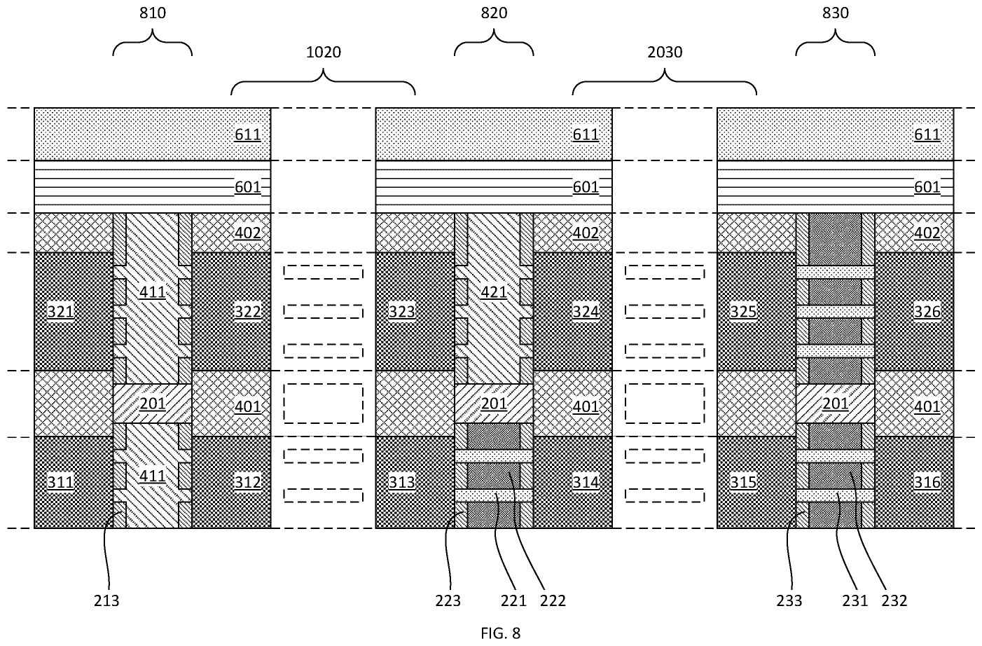

It is to be noted here that upside-up (instead of upside-down) drawings will continue to be used hereinafter for FIGS. 8-12 for the ease of illustration. However, description of the drawings may be provided in a manner that is consistent with processing from the backside of the semiconductor substrate 101.

FIG. 8 is a demonstrative illustration of cross-sectional view of a semiconductor structure in a step of manufacturing thereof according to one embodiment of present invention. More particularly, following the step illustrated in FIG. 7, embodiments of present invention provide removing the semiconductor substrate 101 through, for example, a CMP process, a grinding process, and/or in combination with other selective etching processes. The removal process may thus expose bottom surfaces of the first group of metal gates 310, the bottom surface of the F-SDB 411, and the bottom surfaces of the first group of S/D regions of the first group of FETs 330.

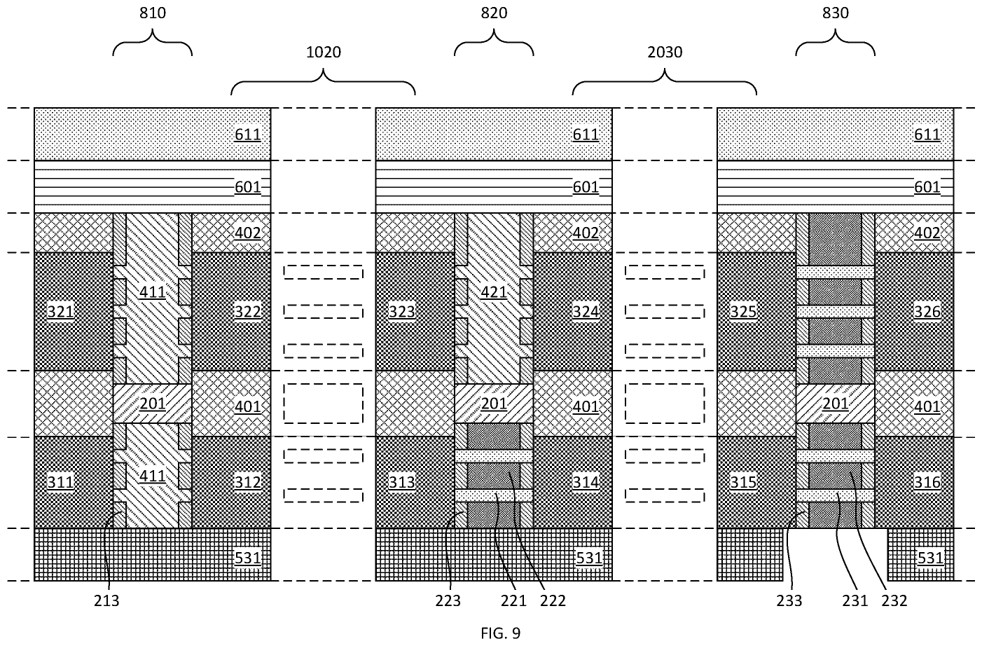

FIG. 9 is a demonstrative illustration of cross-sectional view of a semiconductor structure in a step of manufacturing thereof according to one embodiment of present invention. More particularly, following the step illustrated in FIG. 8, embodiments of present invention provide forming a mask layer, such as an OPL layer, on top of the first group of metal gates 310 and the S/D regions surrounding the first group of metal gates 310. A lithographic patterning process may be applied to pattern the mask layer, thereby creating a hard mask 531 having an opening that exposes, for example, a bottom surface of the stack of metal gates in the third area 830.

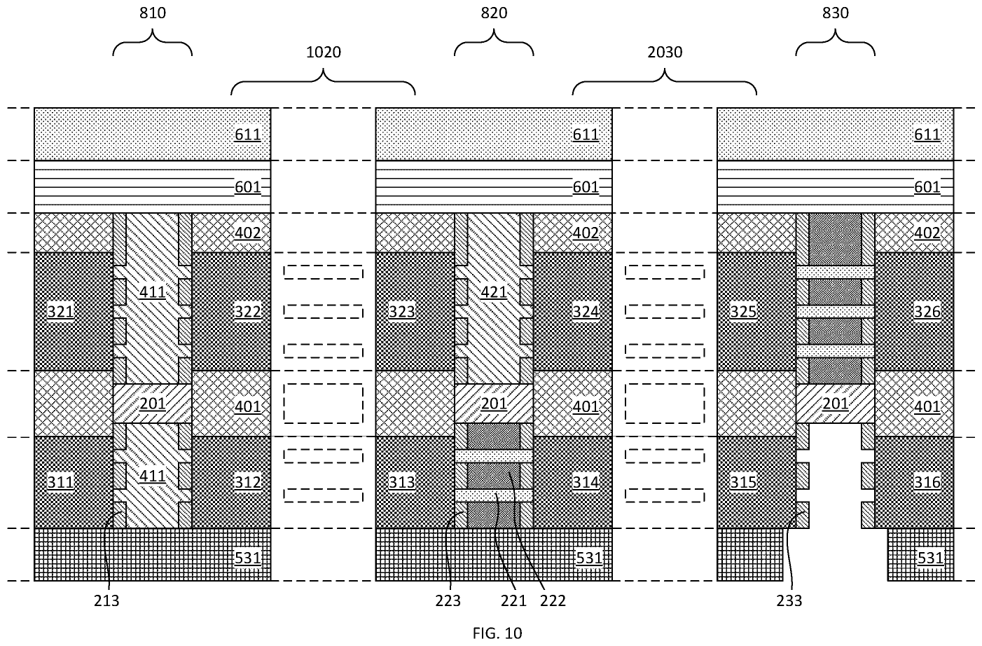

FIG. 10 is a demonstrative illustration of cross-sectional view of a semiconductor structure in a step of manufacturing thereof according to one embodiment of present invention. More particularly, following the step illustrated in FIG. 9, embodiments of present invention provide applying a selective etch process to remove a portion of the gate metal 232, underneath the MDI layer 201, that corresponds to the metal gate, in the third area 830, of the first group of metal gates 310. In removing the portion of the gate metal 232, the selective etch process may be timed or controlled such that it stops when a bottom surface of the MDI layer 201 in the third area 830 is exposed. The removal of the portion of the gate metal 232 may create a third opening underneath the MDI layer 201 in the third area 830.

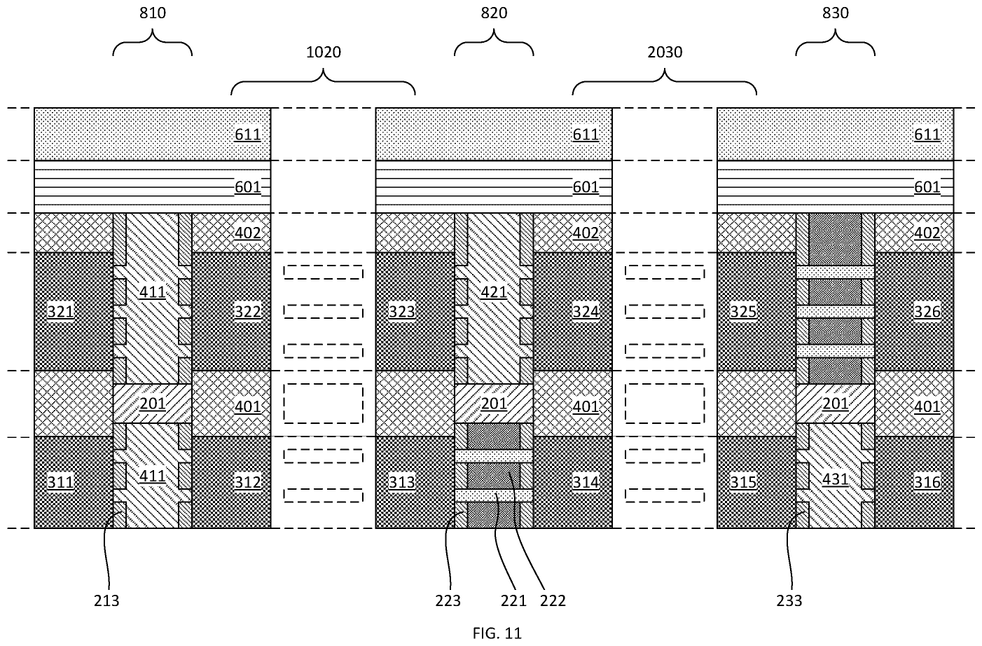

FIG. 11 is a demonstrative illustration of cross-sectional view of a semiconductor structure in a step of manufacturing thereof according to one embodiment of present invention. More particularly, following the step illustrated in FIG. 10, embodiments of present invention provide filling the third opening in the third area 830 with a dielectric material to form a H-SDB 431. The H-SDB 431 may be a first H-SDB and may be formed between a S/D region 315 of a first FET of the first group of FETs 330 and a S/D region 316 of a second FET of the first group of FETs 330. In one embodiment, the first and the second FET of the first group of FETs 330 may have opposite polarities. For example, the first FET of the first group of FETs 330 may be a p-type FET and the second FET of the first group of FETs 330 may be an n-type FET, or vice versa. The H-SDB 431 may be vertically or directly underneath, via the MDI layer 201, a metal gate of the second group of metal gates 320. The dielectric material may be a material same as or different from the dielectric material forming the F-SDB 411, the second H-SDB 421, and/or the MDI layer 201.

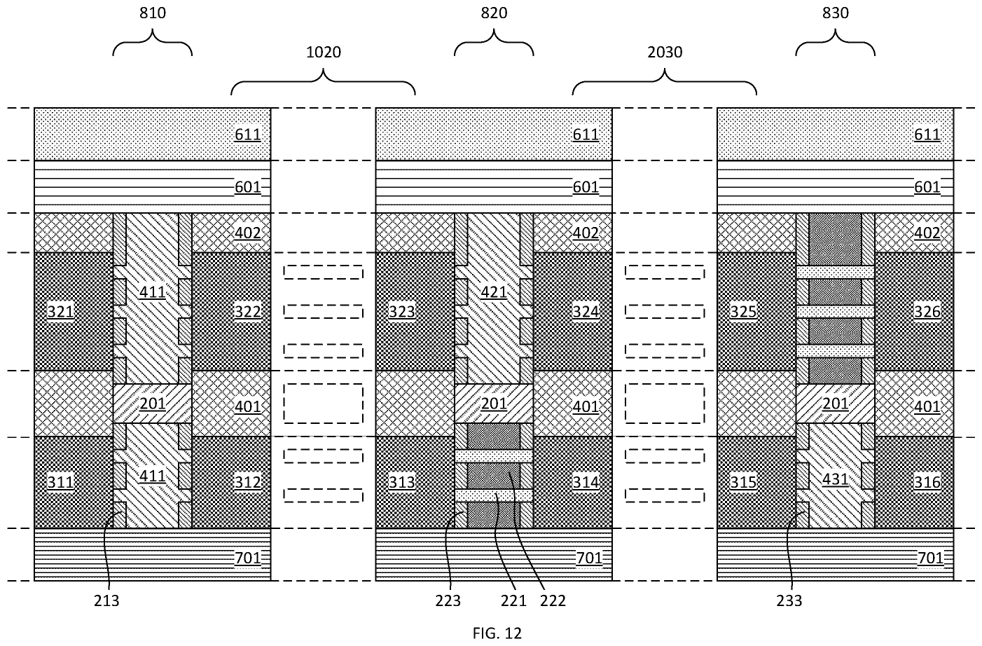

FIG. 12 is a demonstrative illustration of cross-sectional view of a semiconductor structure in a step of manufacturing thereof according to one embodiment of present invention. More particularly, following the step illustrated in FIG. 11, embodiments of present invention provide forming a backside BEOL structure 701 such as a power distribution network (BSPDN), which may include one or more backside power rails (BSPRs), on top of the F-SDB 411, the first H-SDB 431, and the first group of metal gates 310. The backside BEOL structure 701 or the BSPDN may provide conductive connections to at least the first group of S/D regions of the first group of FETs 330.

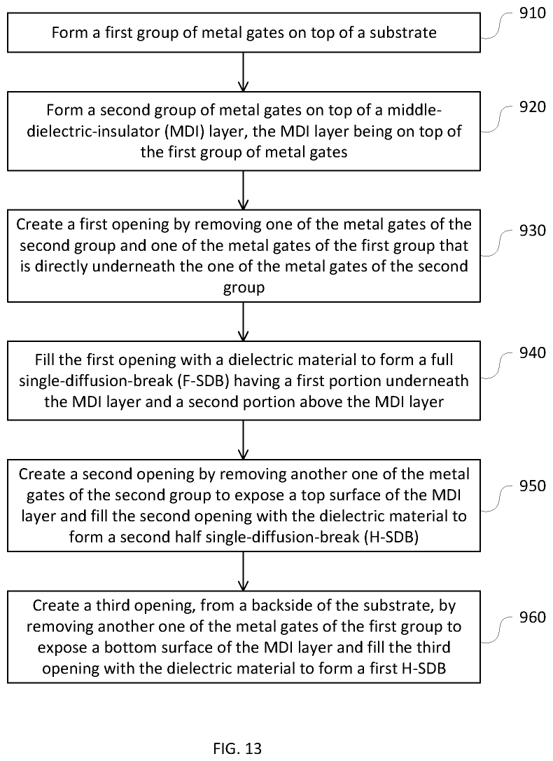

FIG. 13 is a demonstrative illustration of a flow-chart of a method of manufacturing a semiconductor structure according to embodiments of present invention. The method includes (910) forming a first group of metal gates on top of a substrate; (920) forming a second group of metal gates on top of a middle-dielectric-insulator (MDI) layer, the MDI layer being on top of the first group of metal gates; (930) creating a first opening by removing one of the metal gates of the second group and one of the metal gates of the first group that is directly underneath the one of the metal gates of the second group; (940) filling the first opening with a dielectric material to form a full-single-diffusion-break (F-SDB) that has a first portion underneath the MDI layer and a second portion above the MDI layer; (950) creating a second opening by removing another one of the metal gates of the second group to expose a top surface of the MDI layer and filling the second opening with the dielectric material to form a second half-single-diffusion-break (H-SDB); and (960) creating a third opening, from a backside of the substrate, by removing another one of the metal gates of the first group to expose a bottom surface of the MDI layer and filling the third opening with the dielectric material to form a first H-SDB.

Various examples may possibly be described by one or more of the following features in the following numbered clauses:

Clause 1: A semiconductor structure comprising a first group of field-effect-transistors (FETs); a second group of FETs on top of the first group of FETs; and a half-single-diffusion-break (H-SDB) directly underneath one of the FETs of the second group and being separated from the one of the FETs of the second group by a middle-dielectric-insulator (MDI) layer, wherein the H-SDB insulates a source/drain (S/D) region of a first FET of the first group of FETs from a S/D region of a second FET of the first group of FETs. The use of the H-SDB saves a real estate space above the H-SDB such that the saved real estate space may be used in forming another FET.

Clause 2: The semiconductor structure of clause 1, wherein the H-SDB is a first H-SDB, further comprising a second H-SDB directly on top of one of the FETs of the first group and being separated from the one of the FETs of the first group by the MDI layer, wherein the second H-SDB insulates a S/D region of a first FET of the second group of FETs from a S/D region of a second FET of the second group of FETs. The use of the second H-SDB saves a real estate space below the second H-SDB, or more specifically below the MDI layer, for forming an additional FET.

Clause 3: The semiconductor structure of clause 2, further comprising a full-single-diffusion-break (F-SDB) with a first portion underneath the MDI layer and a second portion above the MDI layer, wherein the first portion of the F-SDB insulates a S/D region of a third FET of the first group of FETs from a S/D region of a fourth FET of the first group of FETs, and the second portion of the F-SDB insulates a S/D region of a third FET of the second group of FETs from a fourth FET of the second group of FETs.

Clause 4: The semiconductor structure of clause 1, wherein the first and the second FET of the first group of FETs have opposite polarities.

Clause 5: The semiconductor structure of clause 4, wherein the one of the FETs of the second group is a nanosheet transistor and the H-SDB is directly underneath a metal gate of the nanosheet transistor, the metal gate of the nanosheet transistor surrounding a set of nanosheets.

Clause 6: The semiconductor structure of clause 2, wherein the first and the second FET of the second group of FETs have opposite polarities.

Clause 7: The semiconductor structure of clause 6, wherein the one of the FETs of the first group is a nanosheet transistor and the second H-SDB is directly on top of a metal gate of the nanosheet transistor, the metal gate of the nanosheet transistor surrounding a set of nanosheets.

Clause 8: A semiconductor structure comprising a first group of field-effect-transistors (FETs); a second group of FETs on top of the first group of FETs; and a half-single-diffusion-break (H-SDB) on top of one of the FETs of the first group and being separated from the one of the FETs of the first group by a middle-dielectric-insulator (MDI) layer, wherein the H-SDB insulates a source/drain (S/D) region of a first FET of the second group of FETs from a S/D region of a second FET of the second group of FETs. The use of the H-SDB saves a real estate space below the H-SDB such that the real estate space saved may be used in forming another FET.

Clause 9: The semiconductor structure of clause 8, wherein the H-SDB is a first H-SDB, further comprising a second H-SDB underneath one of the FETs of the second group and being separated from the one of the FETs of the second group by the MDI layer, wherein the second H-SDB insulates a source/drain (S/D) region of a first FET of the first group of FETs from a S/D region of a second FET of the first group of FETs. The use of the second H-SDB saves a real estate space above the second H-SDB, or more specifically above the MDI layer, for forming an additional FET.

Clause 10: The semiconductor structure of clause 9, wherein the one of the FETs of the second group is a nanosheet transistor and the second H-SDB is directly underneath a set of nanosheets of the nanosheet transistor.

Clause 11: The semiconductor structure of clause 10, wherein the first FET of the first group of FETs is a p-type FET and the second FET of the first group of FETs is an n-type FET.

Clause 12: The semiconductor structure of clause 9, further comprising a full-single-diffusion-break (F-SDB) with a first portion underneath the MDI layer and a second portion above the MDI layer, wherein the first portion of the F-SDB is horizontally between two of the FETs of the first group and the second portion of the F-SDB is horizontally between two of the FETs of the second group, and the F-SDB and the MDI layer are made of different dielectric material.

Clause 13: The semiconductor structure of clause 12, wherein the first FET of the second group of FETs is a p-type FET and the second FET of the second group of FETs is an n-type FET.

Clause 14: The semiconductor structure of clause 13, wherein the one of the FETs of the first group is a nanosheet transistor and the first H-SDB is directly on top of a set of nanosheets of the nanosheet transistor.

Clause 15: A method of forming a semiconductor structure comprising forming a first group of metal gates on top of a substrate; forming a second group of metal gates on top of a middle-dielectric-insulator (MDI) layer, the MDI layer being on top of the first group of metal gates; forming a full-single-diffusion-break (F-SDB) through the first and the second group of metal gates; forming a first half-single-diffusion-break (H-SDB) through the first group of metal gates; and forming a second H-SDB through the second group of metal gates.

Clause 16: The method of clause 15, wherein forming the F-SDB and forming the second H-SDB comprises creating a first opening by removing one of the metal gates of the second group and one of the metal gates of the first group, the one of the metal gates of the first group being directly underneath the one of the metal gates of the second group; creating a second opening by removing another one of the metal gates of the second group to expose a top surface of the MDI layer; filling the first opening with a dielectric material to form the F-SDB, the F-SDB having a first portion underneath the MDI layer and a second portion above the MDI layer; and filling the second opening with the dielectric material to form the second H-SDB.

Clause 17: The method of clause 16, wherein forming the first H-SDB comprises creating a third opening, from a backside of the substrate, by removing another one of the metal gates of the first group to expose a bottom surface of the MDI layer; and filling the third opening with the dielectric material to form the first H-SDB.

Clause 18: The method of clause 15, further comprising forming the first group of metal gates and the second group of metal gates in a single replacement-metal-gate process.

Clause 19: The method of clause 15, further comprising epitaxially growing a first group of source/drain (S/D) regions from a first and a second end of multiple sets of nanosheets below the MDI layer.

Clause 20: The method of clause 19, further comprising forming an interlevel dielectric layer on top of the first group of S/D regions; and epitaxially growing a second group of S/D regions from a first and a second end of multiple sets of nanosheets above the MDI layer.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions of various embodiments of present invention have been presented for the purposes of illustration and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. A semiconductor structure comprising:
a first group of field-effect-transistors (FETs);
a second group of FETs on top of the first group of FETs; and
a half-single-diffusion-break (H-SDB) directly underneath one of the FETs of the second group and being separated from the one of the FETs of the second group by a middle-dielectric-insulator (MDI) layer,
wherein the H-SDB insulates a source/drain (S/D) region of a first FET of the first group of FETs from a S/D region of a second FET of the first group of FETs.

2. The semiconductor structure of claim 1, wherein the H-SDB is a first H-SDB, further comprising:
a second H-SDB directly on top of one of the FETs of the first group and being separated from the one of the FETs of the first group by the MDI layer,
wherein the second H-SDB insulates a S/D region of a first FET of the second group of FETs from a S/D region of a second FET of the second group of FETs.

3. The semiconductor structure of claim 2, further comprising:
a full-single-diffusion-break (F-SDB) with a first portion underneath the MDI layer and a second portion above the MDI layer, wherein the first portion of the F-SDB insulates a S/D region of a third FET of the first group of FETs from a S/D region of a fourth FET of the first group of FETs, and the second portion of the F-SDB insulates a S/D region of a third FET of the second group of FETs from a fourth FET of the second group of FETS.

4. The semiconductor structure of claim 1, wherein the first and the second FET of the first group of FETs have opposite polarities.

5. The semiconductor structure of claim 4, wherein the one of the FETs of the second group is a nanosheet transistor and the H-SDB is directly underneath a metal gate of the nanosheet transistor, the metal gate of the nanosheet transistor surrounding a set of nanosheets.

6. The semiconductor structure of claim 2, wherein the first and the second FET of the second group of FETs have opposite polarities.

7. The semiconductor structure of claim 6, wherein the one of the FETs of the first group is a nanosheet transistor and the second H-SDB is directly on top of a metal gate of the nanosheet transistor, the metal gate of the nanosheet transistor surrounding a set of nanosheets.

8. A semiconductor structure comprising:
a first group of field-effect-transistors (FETs);
a second group of FETs on top of the first group of FETs; and
a half-single-diffusion-break (H-SDB) on top of one of the FETs of the first group and being separated from the one of the FETs of the first group by a middle-dielectric-insulator (MDI) layer,
wherein the H-SDB insulates a source/drain (S/D) region of a first FET of the second group of FETs from a S/D region of a second FET of the second group of FETs.

9. The semiconductor structure of claim 8, wherein the H-SDB is a first H-SDB, further comprising:
a second H-SDB underneath one of the FETs of the second group and being separated from the one of the FETs of the second group by the MDI layer,
wherein the second H-SDB insulates a source/drain (S/D) region of a first FET of the first group of FETs from a S/D region of a second FET of the first group of FETs.

10. The semiconductor structure of claim 9, wherein the one of the FETs of the second group is a nanosheet transistor and the second H-SDB is directly underneath a set of nanosheets of the nanosheet transistor.

11. The semiconductor structure of claim 10, wherein the first FET of the first group of FETs is a p-type FET and the second FET of the first group of FETs is an n-type FET.

12. The semiconductor structure of claim 9, further comprising:
a full-single-diffusion-break (F-SDB) with a first portion underneath the MDI layer and a second portion above the MDI layer, wherein the first portion of the F-SDB is horizontally between two of the FETs of the first group and the second portion of the F-SDB is horizontally between two of the FETs of the second group, and the F-SDB and the MDI layer are made of different dielectric material.

13. The semiconductor structure of claim 12, wherein the first FET of the second group of FETs is a p-type FET and the second FET of the second group of FETs is an n-type FET.

14. The semiconductor structure of claim 13, wherein the one of the FETs of the first group is a nanosheet transistor and the first H-SDB is directly on top of a set of nanosheets of the nanosheet transistor.

15. A method of forming a semiconductor structure comprising:
forming a first group of metal gates on top of a substrate;
forming a second group of metal gates on top of a middle-dielectric-insulator (MDI) layer, the MDI layer being on top of the first group of metal gates;
forming a full-single-diffusion-break (F-SDB) through the first and the second group of metal gates;
forming a first half-single-diffusion-break (H-SDB) through the first group of metal gates; and
forming a second H-SDB through the second group of metal gates.

16. The method of claim 15, wherein forming the F-SDB and forming the second H-SDB comprises:
creating a first opening by removing one of the metal gates of the second group and one of the metal gates of the first group, the one of the metal gates of the first group being directly underneath the one of the metal gates of the second group;
creating a second opening by removing another one of the metal gates of the second group to expose a top surface of the MDI layer;
filling the first opening with a dielectric material to form the F-SDB, the F-SDB having a first portion underneath the MDI layer and a second portion above the MDI layer; and
filling the second opening with the dielectric material to form the second H-SDB.

17. The method of claim 16, wherein forming the first H-SDB comprises:
creating a third opening, from a backside of the substrate, by removing another one of the metal gates of the first group to expose a bottom surface of the MDI layer; and
filling the third opening with the dielectric material to form the first H-SDB.

18. The method of claim 15, further comprising forming the first group of metal gates and the second group of metal gates in a single replacement-metal-gate process.

19. The method of claim 15, further comprising epitaxially growing a first group of source/drain (S/D) regions from a first and a second end of multiple sets of nanosheets below the MDI layer.

20. The method of claim 19, further comprising:
forming an interlevel dielectric layer on top of the first group of S/D regions; and
epitaxially growing a second group of S/D regions from a first and a second end of multiple sets of nanosheets above the MDI layer.
